(19) United States
(12) Patent Application Publication
(10) Pub. No.: US 2025/0359359 A1
(43) Pub. Date: Nov. 20, 2025

(54) AVALANCHE PHOTODIODE WITH MULTI-STAGE MESA STRUCTURE

(71) Applicant: Lumentum Operations LLC, San Jose, CA (US)

(72) Inventors: Takashi TOYONAKA, Yokohama (JP); Shigehisa TANAKA, Tokyo (JP); Hideaki MATSUZAKI, Isehara (JP)

(21) Appl. No.: 18/932,305

(22) Filed: Oct. 30, 2024

(30) Foreign Application Priority Data
May 17, 2024 (JP) 2024080650
Sep. 5, 2024 (JP) 2024153278

(51) Int. Cl. H01L 31/107; H01L 31/0232; H01L 31/0352

(52) U.S. Cl. CPC H10F 30/225; H10F 77/147; H10F 77/413

(57) ABSTRACT

Provided is an avalanche photodiode that is excellent in characteristics and reliability. The avalanche photodiode includes a substrate, an n-type contact layer formed above the substrate, and a mesa structure formed above the n-type contact layer. The mesa structure includes a multiplication layer, a light absorption layer, and a p-type contact layer. The multiplication layer is larger than the light absorption layer in plan view, and the light absorption layer is larger than the p-type contact layer in plan view.

### CROSS-REFERENCE TO RELATED APPLICATIONS

This Patent Application claims priority to Japan Patent Application No. 2024-153278, filed on Sep. 5, 2024, and to Japan Patent Application No. 2024-080650, filed on May 17, 2024. The disclosures of the prior Applications are considered part of and are incorporated by reference into this Patent Application.

### TECHNICAL FIELD

The present disclosure relates generally to an avalanche photodiode.

### BACKGROUND

An avalanche photodiode (also referred to herein as an “APD”) is one type of a semiconductor light-receiving element. In general, an APD includes a light absorption layer that absorbs light and generates carriers and a multiplication layer that multiplies the generated carriers.

### SUMMARY

An APD, which can require high-speed operation, is often preferred to have a mesa structure that can achieve a small element capacitance. In many cases, the APD is also driven at a higher voltage than a positive-intrinsic-negative photodiode (PIN-PD). For example, when an intense electric field is applied to a multiplication layer, a local breakdown may occur at a side surface of the multiplication layer included in the mesa structure. The occurrence of a breakdown inhibits the APD from operating normally. In the same manner, a side surface of a light absorption layer included in the mesa structure may also experience an increase in leakage current at the side surface due to the intense electric field, and the increase may adversely affect characteristics.

Some implementations described herein include an avalanche photodiode that suppresses an occurrence of a breakdown and supports high-speed operation.

In some implementations, an avalanche photodiode includes: a substrate; an n-type contact layer formed above the substrate; a multiplication layer formed above the n-type contact layer; a light absorption layer formed above the multiplication layer; and a p-type contact layer formed above the light absorption layer. The multiplication layer, the light absorption layer, and the p-type contact layer form a mesa structure. The multiplication layer is larger than the light absorption layer in plan view, and the light absorption layer is larger than the p-type contact layer in plan view.

### BRIEF DESCRIPTION OF THE DRAWINGS

FIG. 1 is a top view of an avalanche photodiode according to a first example implementation of the present invention.

FIG. 2 is a schematic cross-sectional view taken along the line II-II of the avalanche photodiode illustrated in FIG. 1.

FIG. 3A is a schematic cross-sectional view for illustrating a part of an avalanche photodiode according to Comparative Example 1.

FIG. 3B is a schematic cross-sectional view for illustrating a part of an avalanche photodiode according to Comparative Example 2.

FIG. 3C is a schematic cross-sectional view for illustrating a part of an avalanche photodiode according to Comparative Example 3.

FIG. 3D is a schematic cross-sectional view for illustrating a part of the avalanche photodiode according to the first example implementation.

FIG. 4 is a schematic cross-sectional view of an avalanche photodiode according to a second example implementation of the present invention.

FIG. 5 is a schematic cross-sectional view of an avalanche photodiode according to a modification example of the second example implementation.

FIG. 6 is a schematic cross-sectional view of an avalanche photodiode according to a third example implementation of the present invention.

FIG. 7 is a top view of an avalanche photodiode according to a fourth example implementation of the present invention.

FIG. 8 is a schematic cross-sectional view taken along the line VIII-VIII of the avalanche photodiode illustrated in FIG. 7.

### DETAILED DESCRIPTION

A specific and detailed description is provided below of example implementations of the present invention with reference to the drawings. Members denoted by a same reference symbol throughout the drawings have a same or an equivalent function, and a repetitive description of the members is omitted. Note that sizes of graphics are not always to scale.

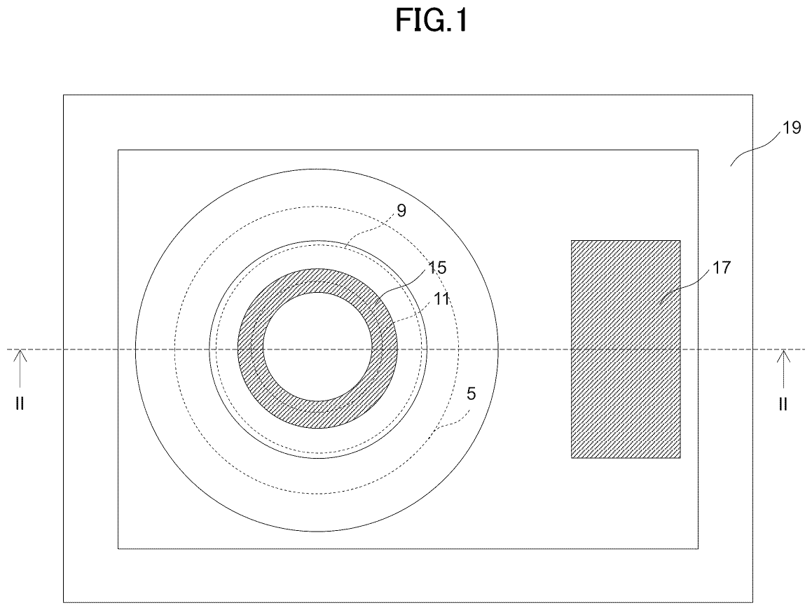

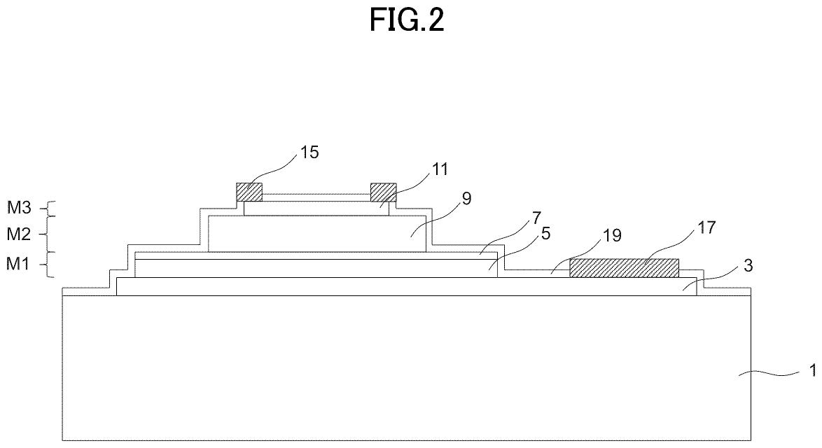

FIG. 1 is a top view of an avalanche photodiode (APD) according to a first example implementation of the present invention. The APD according to the first example implementation may be of a top-illuminated type. Positions of outer edges of a multiplication layer 5, a light absorption layer 9, and a p-type contact layer 11 (not shown in the top view of FIG. 1) are indicated by the broken lines. FIG. 2 is a cross-sectional view for schematically illustrating a cross section taken along the line II-II of FIG. 1.

The APD may include a semiconductor multilayer on a substrate 1. The substrate 1 may be a semi-insulating, insulating, or n-type semiconductor. The semiconductor multilayer may include an n-type contact layer 3, the multiplication layer 5, a p-type electric field control layer 7, the light absorption layer 9, and the p-type contact layer 11. The n-type contact layer 3 may be a semiconductor layer doped with n-type impurities. For example, an impurity concentration thereof may be 1×10¹⁸ cm⁻³ or more. An n-side electrode 17 may be connected to the n-type contact layer 3. The multiplication layer 5 and the light absorption layer 9 may be undoped layers that are intentionally doped with no impurities. In this case, the undoped layer may be a layer having an impurity concentration at a background level, and for example, the impurity concentration may be less than 1×10¹⁶ cm⁻³. In this case, the light absorption layer 9 may be thicker than the multiplication layer 5 in terms of a layer thickness. The p-type electric field control layer 7 may be a layer for creating a difference between electric field intensities applied to the light absorption layer 9 and the multiplication layer 5. The p-type contact layer 11 may be a semiconductor layer doped with p-type impurities. For example, the impurity concentration may be 1×10¹⁸ cm⁻³ or more. A p-side electrode 15 may be connected to the p-type contact layer 11. The p-side electrode 15 may be a substantially annular ring in plan view, and a region inside the annular ring serves as a light-receiving portion. When the substrate 1 is an n-type semiconductor, the n-type contact layer 3 is not required to be placed.

Examples of the respective semiconductor layers are given below. The substrate 1 may be formed of InP doped with Fe. The n-type contact layer 3 may be formed of InP, the multiplication layer 5 may be formed of InAlAs, the electric field control layer 7 may be formed of InP, the light absorption layer 9 may be formed of InGaAs, and the p-type contact layer 11 may be formed of InGaAs. In this case, a band gap of the light absorption layer 9 may be set to support light absorption of from 1,250 nanometers (nm) to 1,600 nm. Those are merely examples, and other materials may be used, and the band gap may be set to support another wavelength band.

In the APD according to the first example implementation, at least a region from the multiplication layer 5 to the p-type contact layer 11 may have a mesa structure. An insulating film 19 may be placed on a surface of the substrate 1 and on side surface of the mesa structure. The insulating film 19 may be also placed on an upper portion of the mesa structure. The insulating film 19 on the upper portion of the mesa structure and the insulating film 19 placed on the side surfaces of the mesa structure may comprise different materials and may differ in thickness.

The mesa structure may be circular in plan view. In the mesa structure in the first example implementation of the present invention, the multiplication layer 5 may be the largest in plan view, and the light absorption layer 9 may be the second largest. The p-type contact layer 11 may be the smallest. In other words, the mesa structure may be a three-stage structure of a lower stage M1, a middle stage M2, and an upper stage M3. In the first example implementation, the lower stage M1 may include the multiplication layer 5 and the electric field control layer 7. The middle stage M2 may include the light absorption layer 9. The upper stage M3 may include the p-type contact layer 11. In FIG. 1, centers of the multiplication layer 5, the light absorption layer 9, and the p-type contact layer 11, which are each circular in plan view, may be aligned. However, the centers of the multiplication layer 5, the light absorption layer 9, and the p-type contact layer 11 are not required to be aligned.

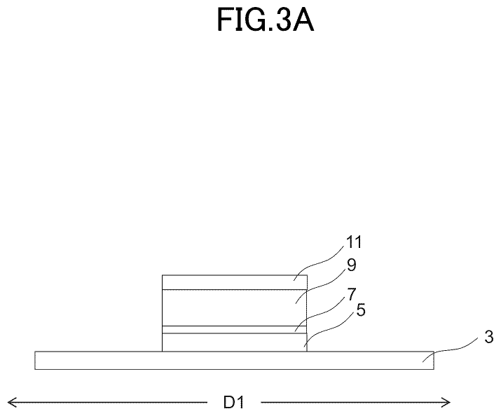

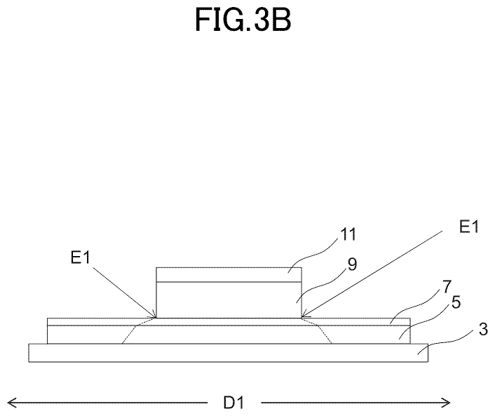

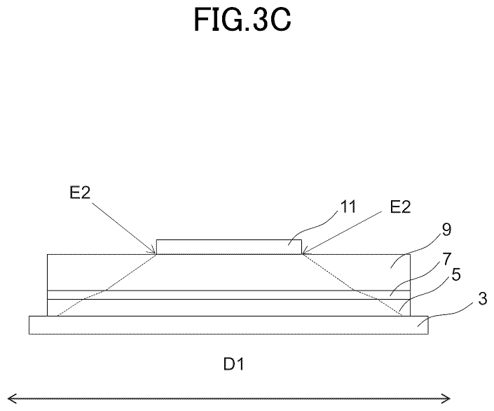

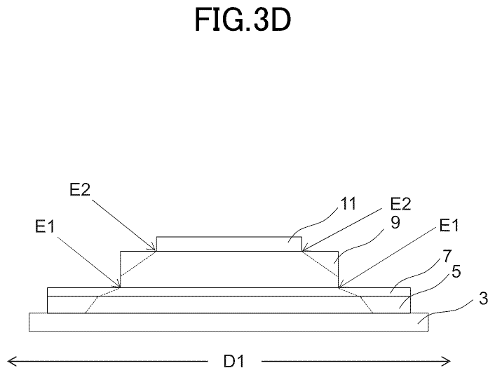

Effects of the first example implementation are described through use of Comparative Examples 1, 2, and 3. FIG. 3A, FIG. 3B, and FIG. 3C are cross-sectional views for illustrating parts of APDs according to the Comparative Examples 1, 2, and 3, respectively. For the sake of simplification of description, insulating films and electrodes are not shown. In this case, the p-type contact layer 11 has the same size in plan view between the first example implementation and Comparative Examples 1, 2, and 3. The multiplication layer 5 and the electric field control layer 7 also have the same size in plan view between the first example implementation and Comparative Examples 2 and 3.

In Comparative Example 1, the mesa structure includes no steps. Comparative Example 2 is an example in which the mesa structure is a two-stage structure, and the multiplication layer 5 and the electric field control layer 7 are each larger than the light absorption layer 9 in the same manner as in the first example implementation. Comparative Example 3 is an example in which the mesa structure is a two-stage structure, and the multiplication layer 5, the electric field control layer 7, and the light absorption layer 9 have the same size in plan view and are each larger than the p-type contact layer 11. In this case, the multiplication layer 5 is set to have the same size in plan view between the first example implementation and Comparative Examples 2 and 3. The wording “the same size in plan view” as used herein refers to a state in which the side surfaces of the mesa structure are substantially aligned as illustrated in FIG. 2 and FIG. 3A to FIG. 3D.

In the APD, a most intense electric field may be applied to the multiplication layer 5, which may be an undoped layer. A second most intense electric field may be applied to the light absorption layer 9. The two layers may be depleted in accordance with an intensity of an electric field, and operate for increase in carriers and light absorption. The p-type contact layer 11 may be a high-concentration p-type semiconductor layer, and when a reverse bias voltage is applied to the p-side electrode 15, an electric field may be applied to the light absorption layer 9, the electric field control layer 7, and the multiplication layer 5 between the p-type contact layer 11 and the n-type contact layer 3. In this case, the electric field control layer 7 may be a high-concentration p-type layer, and a concentration of the electric field control layer 7 may be adjusted so that an appropriate electric field intensity is applied to each of the light absorption layer 9 and the multiplication layer 5. In Comparative Example 1, a side surface of the p-type contact layer 11 and side surfaces of the other semiconductor layers are substantially aligned. Accordingly, an electric field intensity distribution at a surface of the multiplication layer 5 on the electric field control layer 7 side is approximately uniform. However, a voltage at which a breakdown occurs tends to be lower at the side surface of the mesa structure than in a central portion. Consequently, when the applied voltage is increased, a breakdown occurs at the side surface of the multiplication layer 5, and the APD no longer operates normally.

In Comparative Example 2, the side surface of the p-type contact layer 11 and the side surface of the multiplication layer 5 are not aligned. Moreover, the side surface of the p-type contact layer 11 and the side surface of the light absorption layer 9 are substantially aligned. In the same manner as in Comparative Example 1, an electric field may be applied to the light absorption layer 9, the electric field control layer 7, and the multiplication layer 5. A contact point between the side surface of the light absorption layer 9 and the electric field control layer 7 is here defined as “edge E1.” The electric field in the electric field control layer 7 spreads from the edge E1, which serves as a starting point, in a first direction D1 perpendicular to a stacking direction of the semiconductor multilayer to be applied to the multiplication layer 5. However, the electric field control layer 7 is thinner than the multiplication layer 5, and hence the electric field does not greatly spread. The electric field also spreads in the multiplication layer 5 in the same manner. The spread of an electric field distribution is indicated by dotted lines. This is merely an image for description, and does not indicate the exact spread of the electric field distribution. It is possible to lower the electric field intensity at the side surface of the multiplication layer 5 compared to the central portion of the multiplication layer 5 by increasing a distance between the side surface of the multiplication layer 5 and the edge E1. For example, in FIG. 3B, the electric field distribution does not reach the side surface of the multiplication layer 5, and a breakdown does not occur at the side surface. That is, it is possible to suppress a breakdown by forming the multiplication layer 5 to be larger than the light absorption layer 9 in plan view so that the electric field intensity does not cause a breakdown at the side surface of the multiplication layer 5. However, the structure of Comparative Example 2 causes another problem. The electric field distribution in the electric field control layer 7 is not uniform in the first direction D1, and is a distribution in which the electric field intensity directly below the edge E1 is locally high. This intense electric field immediately below the edge E1 is transmitted to the multiplication layer 5, and the electric field distribution in the multiplication layer 5 also exhibits a high electric field intensity immediately below the edge E1. As a result, a local breakdown may occur immediately below the edge E1. Consequently, Comparative Example 2 can suppress a breakdown at the side surface of the multiplication layer 5, but a breakdown may occur immediately below the edge E1.

In Comparative Example 3, the mesa structure has two stages of the p-type contact layer 11 and other layers. The side surface of the light absorption layer 9 and the side surfaces of the electric field control layer 7 and the multiplication layer 5 are substantially aligned. A contact point between the side surface of the p-type contact layer 11 and the light absorption layer 9 is here defined as “edge E2.” The electric field distribution in the light absorption layer 9 spreads from the edge E2, which serves as a starting point, in the first direction D1. In the same manner as in Comparative Example 2, the image of the electric field distribution is indicated by the dotted lines. In the same manner as in Comparative Example 2, the electric field distribution does not reach the side surface of the multiplication layer 5, and no breakdown occurs at the side surface of the multiplication layer 5. In addition, there is no region corresponding to the region immediately below the edge E1, and there is no location at which the electric field intensity is high enough to cause a breakdown inside the multiplication layer 5. The electric field is also concentrated immediately below the edge E2. However, the light absorption layer 9 is a relatively thick layer, and such an intense electric field does not affect the multiplication layer 5 to such an extent as to cause a breakdown. Thus, Comparative Example 3 can suppress occurrence of a breakdown in the multiplication layer 5. However, Comparative Example 3 is disadvantageous in high-speed operation in terms of capacitance. The capacitance is proportional to the size of the region in plan view in which the electric field spreads. As illustrated in FIG. 3C, the electric field spreads from the edge E2 over a large region of the multiplication layer 5. Consequently, the capacitance is large, thereby hindering the high-speed operation.

To summarize the above description, Comparative Example 1 has the lowest parasitic capacitance, but a breakdown may occur at the side surface of the multiplication layer 5. Comparative Example 2 is superior to Comparative Example 3 in terms of parasitic capacitance, but a breakdown may occur inside the multiplication layer 5. Comparative Example 3 is unlikely to have an occurrence of a breakdown in the multiplication layer 5, but cannot support high-speed operation in terms of parasitic capacitance.

For comparison to Comparative Examples 1, 2, and 3, a partial structure of the APD according to the first example implementation is illustrated in FIG. 3D. In the APD according to the first example implementation, the p-type contact layer 11, the light absorption layer 9, and the multiplication layer 5 differ from each other in size in plan view. That is, the side surfaces of the p-type contact layer 11, the light absorption layer 9, and the multiplication layer 5 are not aligned. In the same manner as in Comparative Examples 2 and 3, the spread of the electric field distribution is indicated by dotted lines in FIG. 3D. As illustrated in FIG. 3D, the electric field distribution in the light absorption layer 9 spreads from the edge E2, which serves as the starting point, in the first direction D1, and the electric field is transmitted to the multiplication layer 5 via the electric field control layer 7. In the same manner as in Comparative Examples 2 and 3, the electric field distribution does not reach the side surface of the multiplication layer 5. Thus, no breakdown occurs at the side surface of the multiplication layer 5. Further, the electric field is concentrated immediately below the edge E1, which causes electric field intensity to become higher than in other regions. However, the electric field intensity is lower than immediately below the edge E1 in Comparative Example 2, and no breakdown occurs inside the multiplication layer 5. The reason is as follows. That is, Comparative Example 2 exhibits a state in which the side surfaces of the p-type contact layer 11 and the light absorption layer 9 are aligned and an intense electric field is also applied to the side surface of the light absorption layer 9. Thus, the electric field intensity concentrated immediately below the edge E1 in Comparative Example 2 is high. Meanwhile, in the first example implementation, the side surfaces of the p-type contact layer 11 and the light absorption layer 9 are not aligned. As indicated by the dotted lines in FIG. 3D, the electric field spreads from the edge E2 toward the side surface of the light absorption layer 9, and the electric field intensity decreases in accordance with the spread. Even when the decreased electric field intensity is concentrated immediately below the edge E1, the electric field intensity is not high enough to cause a breakdown in the multiplication layer 5. As described above, in the first example implementation, a breakdown in the multiplication layer 5 can be suppressed. In addition, in the first example implementation, compared to Comparative Example 3, two reasons that the size of the light absorption layer 9 in plan view is smaller than the multiplication layer 5 and that the spread of the electric field in the multiplication layer 5 is small enable the parasitic capacitance to be reduced to a lower level than in Comparative Example 3, thereby enabling the high-speed operation to be supported. To give a further description, the spread of the electric field in the light absorption layer 9 reaches the side surface of the light absorption layer 9 before reaching an interface between the light absorption layer 9 and the electric field control layer 7. Thus, the spread of the electric field from the edge E2 to the n-type contact layer 3 in the first example implementation is narrower than in Comparative Example 3. The region in which the parasitic capacitance occurs is the region in which the electric field spreads. In the first example implementation, the multiplication layer 5, which serves as a factor in generating a parasitic capacitance, is larger in plan view than the p-type contact layer 11 and the light absorption layer 9, but the electric field does not spread over the entire region, and hence an increase in parasitic capacitance is suppressed. With the above-mentioned configuration, an APD excellent in high-speed operation with suppressed occurrence of a breakdown is achieved.

The light absorption layer 9 is an important layer that determines characteristics of the APD, and has a desired size in order to achieve both high-speed operation and a large light- receiving diameter. A surface area that is larger in plan view is superior in terms of the light-receiving diameter, but the capacity becomes larger, which is disadvantageous in high-speed operation. In contrast, a surface area that is smaller is advantageous in high-speed operation, but is disadvantageous in terms of the light-receiving diameter, and optical alignment becomes more difficult. In addition to this viewpoint, the suppression of a breakdown in the multiplication layer 5 is taken into account to determine the size and thickness of the light absorption layer 9. For example, the size, here, the diameter due to the mesa structure being circular, of the light absorption layer 9 of the APD that supports 25 gigabits per second (Gbps) in plan view may be preferred to be around 20 micrometers (μm). Meanwhile, from the viewpoint of the suppression of a breakdown, with the spread of the electric field being taken into account, it may be desired that the p-type contact layer 11 be 1 μm or more smaller in diameter and the multiplication layer 5 be 1 μm or more larger in diameter than the light absorption layer 9. In addition, with manufacturing variations being taken into account, it may be preferred that the diameter of the multiplication layer 5 be 2 μm or more larger than the diameter of the light absorption layer 9. Moreover, it may be preferred that the diameter of the p-type contact layer 11 be 2 μm or more smaller than the diameter of the light absorption layer 9. Further, as illustrated in FIG. 3D, the thickness of the light absorption layer 9 may be determined so that the spread of the electric field in the light absorption layer 9 reaches the side surface of the light absorption layer 9 before reaching the interface between the light absorption layer 9 and the electric field control layer 7.

For the sake of simplification of description, the side surface of the mesa structure is illustrated as a vertical surface, but is not limited thereto. For example, the side surface of the mesa structure may be an inclined surface. When the side surface of the mesa structure is, for example, forward tapered, strictly speaking, the multiplication layer 5 and the electric field control layer 7 cannot be said to have the same size in plan view (the multiplication layer 5 may be slightly larger). However, in the present application, two semiconductor layers are defined as having the same size (that is, the side surfaces of both layers are aligned) as long as the surface of the lower semiconductor layer is not exposed at the interface between the two semiconductor layers. In contrast, two semiconductor layers are defined as differing in size in plan view (that is, the side surfaces of both layers are not aligned) when, as seen at the interface between the electric field control layer 7 and the light absorption layer 9, the surface of the electric field control layer 7 is exposed from the light absorption layer 9. Another layer may be included in each stage of the mesa structure. For example, the p-type contact layer 11 may be formed of a plurality of layers in the upper stage M3.

Further, the mesa structure has a circular shape in plan view in the above-mentioned example, but is not limited thereto. For example, the mesa structure may have an elliptical shape or a polygonal shape.

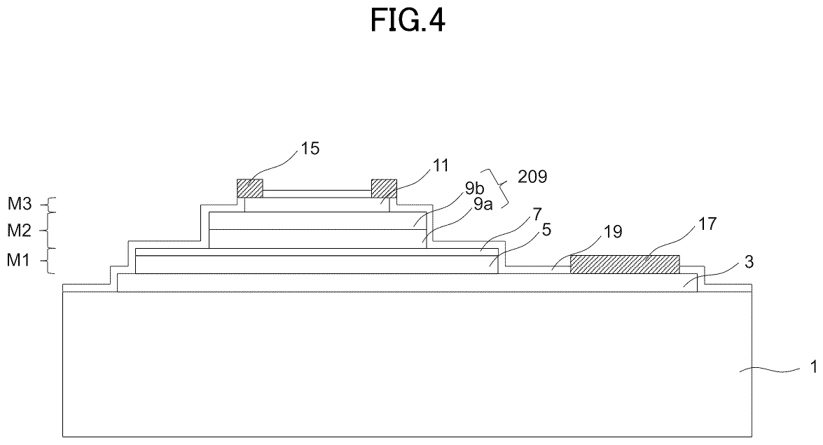

FIG. 4 is a schematic cross-sectional view of an APD according to a second example implementation of the present invention. The second example implementation differs from the first example implementation in that a light absorption layer 209 has a two-layer structure. Structures of other portions in the second example implementation are the same as those in the first example implementation.

In the second example implementation, the light absorption layer 209 may be formed of a first light absorption layer 9a and a second light absorption layer 9b. The first light absorption layer 9a and the second light absorption layer 9b may have the same size in plan view (side surfaces thereof may be substantially aligned). The first light absorption layer 9a may be an InGaAs layer that may be an undoped layer intentionally doped with no impurities. The second light absorption layer 9b may be a low-concentration p-type InGaAs layer doped with p-type impurities having a concentration that is low enough to form a depletion layer. The “concentration that is low enough to form a depletion layer” as used herein refers to, for example, an impurity concentration of less than 1×10¹⁷ cm⁻³. More preferably, the impurity concentration of the second light absorption layer 9b is 0.5×10¹⁷ cm⁻³ or less. The semiconductor material is merely an example.

The APD according to the first example implementation suppresses the occurrence of a breakdown in the multiplication layer 5. However, the electric field also concentrates below the edge E2, which is the contact point between the side surface of the p-type contact layer 11 and the light absorption layer 9, and there is a possibility that a breakdown may occur in the light absorption layer 9. The APD according to the second example implementation suppresses the occurrence of a breakdown in the light absorption layer 9.

When a low-concentration p-type semiconductor layer (second light absorption layer 9b) is sandwiched between the p-type contact layer 11 and the undoped first light absorption layer 9a, a location at which the electric field intensity is the highest in the light absorption layer 209 may be an interface between the first light absorption layer 9a and the second light absorption layer 9b. Thus, the electric field intensity at an interface between the second light absorption layer 9b and the p-type contact layer 11 may be lower than the electric field intensity at the interface between the first light absorption layer 9a and the second light absorption layer 9b. The electric field may be concentrated in the region immediately below the edge E2, and the electric field intensity may be higher than that at the vicinity of the center of the light absorption layer 209. However, the electric field intensity at the interface between the p-type contact layer 11 and the second light absorption layer 9b may be low in the first place, and hence even when the electric field is concentrated in the region immediately below the edge E2, a breakdown voltage may not be reached, thereby being able to suppress the occurrence of a breakdown in the light absorption layer 209.

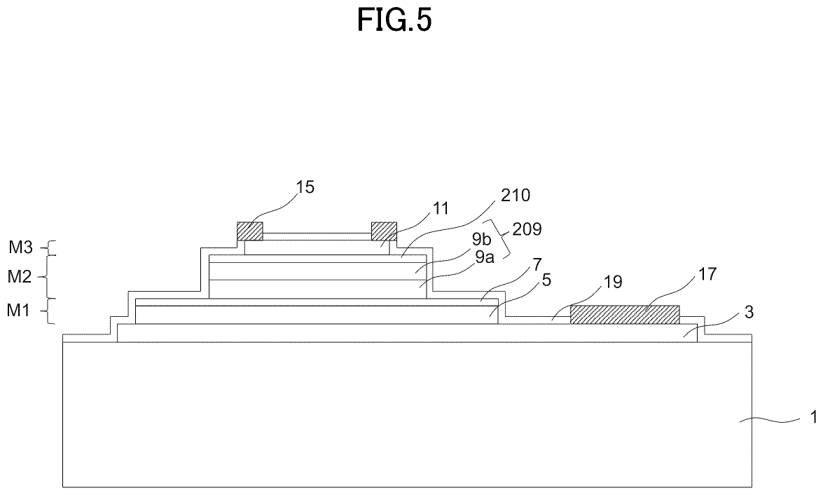

FIG. 5 is a schematic cross-sectional view of an APD according to a modification example of the second example implementation. The modification example differs from the second example implementation in that an etching stop layer 210 is placed between the second light absorption layer 9b and the p-type contact layer 11. In this case, the etching stop layer 210 may have the same size as that of the second light absorption layer 9b in plan view. That is, the etching stop layer 210 may be placed in the middle stage M2 of the mesa structure. Specifically, the etching stop layer 210 may be an uppermost layer of the middle stage M2, and may be formed of a material different from that of a lowermost layer (in this case, the p-type contact layer 11) of the upper stage M3. For example, when the p-type contact layer 11 is formed of InGaAs, the etching stop layer 210 may be formed of InGaAsP. The etching stop layer 210 may be formed of InGaAlAs instead. In addition, the etching stop layer 210 may be a p-type semiconductor layer.

The mesa structure having a plurality of stages may be formed by performing etching a plurality of times after epitaxial growth of a semiconductor multilayer on the substrate 1. For example, the upper stage M3 may be formed by masking a region to be finally left as the upper stage M3 and removing the other region. When the etching stop layer 210 is placed, it may be possible to prevent the middle stage M2 from being etched together at a time of formation of the upper stage M3, thereby being able to stably form the mesa structure having a plurality of stages. The etching stop layer 210 may be placed in the first example implementation.

The electric field control layer 7 may also function as an etching stop layer. The electric field control layer 7 may be an uppermost layer of the lower stage M1. Thus, when the uppermost layer of the lower stage M1 and a lowermost layer of the middle stage M2 are formed of different materials, the uppermost layer of the lower stage M1 functions as an etching stop layer at a time of formation of the middle stage M2. In this case, the electric field control layer 7, which is the uppermost layer of the lower stage M1, may be formed of InP, and the lowermost layer of the middle stage M2 may be the first light absorption layer 9a formed of InGaAs. Those two layers are formed of different materials, and hence the electric field control layer 7 functions as an etching stop layer at the time of formation of the middle stage M2, and the middle stage M2 is formed with stability.

It is possible to form the mesa structure having a plurality of stages by controlling an etching time even without placing an etching stop layer. Thus, a three-stage mesa structure can also be formed in the first example implementation. Consequently, the electric field control layer 7 may be included in the middle stage M2.

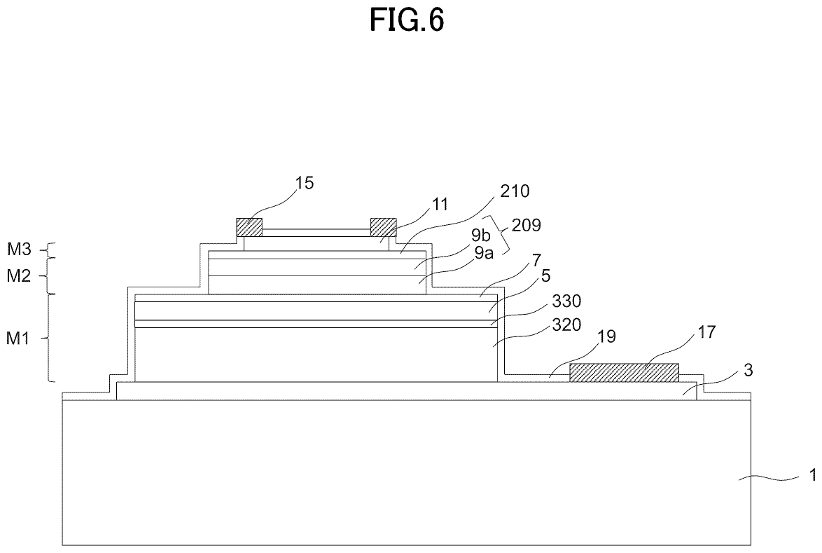

FIG. 6 is a schematic cross-sectional view of an APD according to a third example implementation of the present invention. The third example implementation differs from the second example implementation in that an electron transit layer 320 and an electric field reduction layer 330 are placed between the n-type contact layer 3 and the multiplication layer 5. In this case, the electron transit layer 320 and the electric field reduction layer 330 have the same size as that of the multiplication layer 5 in plan view (that is, side surfaces of both layers are substantially aligned). That is, the electron transit layer 320 and the electric field reduction layer 330 may be placed in the lower stage M1 of the mesa structure.

The electron transit layer 320 may be an undoped layer, and may be a layer having a larger band gap than that of the light absorption layer 209. Specifically, the electron transit layer 320 may be a semiconductor layer having a band gap that does not absorb a wavelength of light to be received. Meanwhile, the electric field reduction layer 330 may be a high-concentration n-type semiconductor layer, and may be a layer for creating a difference in electric field intensity between the electron transit layer 320 and the multiplication layer 5. The electron transit layer may be an undoped layer, and may be depleted during operation of the APD. This produces an effect of reducing the capacitance of the entire APD.

In the third example implementation as well, the above-mentioned APD that suppresses the occurrence of breakdowns at the side surface of the multiplication layer 5 and the light absorption layer 209 and inside thereof and supports the high-speed operation is achieved. Further, the electron transit layer 320 and the electric field reduction layer 330 may be placed in the APD described in the first example implementation.

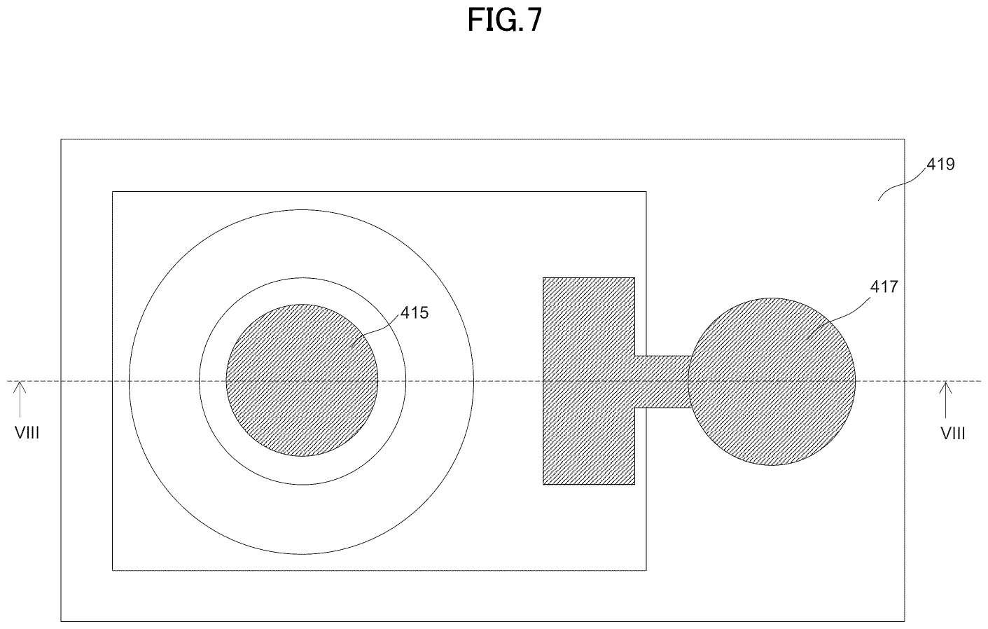

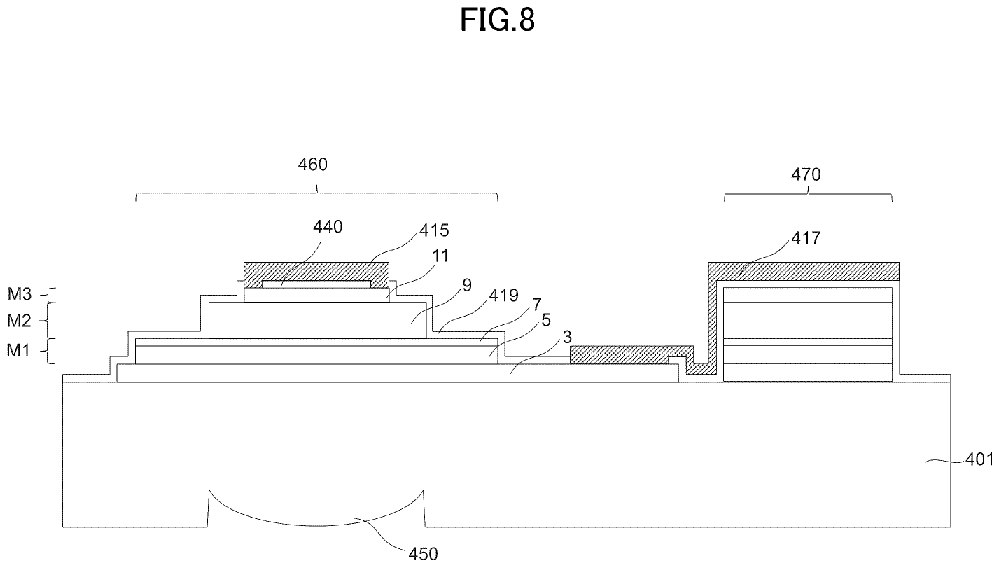

FIG. 7 is a schematic view of an avalanche photodiode (APD) according to a fourth example implementation of the present invention. The APD according to the fourth example implementation may be of a back-illuminated type, and FIG. 7 is a top view, while FIG. 8 is a cross-sectional view for schematically illustrating a cross section taken along the line VIII-VIII of FIG. 7.

A semiconductor multilayer of the APD according to the fourth example implementation may be the same as that in the first example implementation. A main difference therebetween is that a lens 450 may be formed on a back surface of a substrate 401. In addition, an n-side electrode 417 and a p-side electrode 415 differ in shape. Further, in addition to a first mesa structure 460 having a light-receiving function, a second mesa structure 470 on which a part of the n-side electrode 417 is placed is provided.

The lens 450 formed on the back surface of the substrate 401 may have an effect of collecting entering light on the light absorption layer 9 and increasing light sensitivity. The lens 450 may be omitted. A multilayer structure of the first mesa structure 460 may be the same as that of the mesa structure in the first example implementation, and may suppress an occurrence of a breakdown as described above. A reflection film 440 formed of an insulating film may be placed on an upper surface of the p-type contact layer 11. In addition, the circular p-side electrode 415 may be placed on an uppermost portion of the first mesa structure 460. An insulating film 419 may be placed on the side surfaces of the first mesa structure 460 and the second mesa structure 470 described later. The reflection film 440 and the insulating film 419 may be formed of the same material.

The APD according to the fourth example implementation may include the second mesa structure 470. The semiconductor multilayer included in the second mesa structure 470 may be the same as that of the first mesa structure 460. The second mesa structure 470 may be a mesa structure that does not have a stepped structure having a circular shape in plan view. The same stepped structure as that of the first mesa structure 460 may be formed. The n-side electrode 417 may be placed on the upper surface of the second mesa structure 470. The n-side electrode 417 may be connected to the n-type contact layer 3 via the side surface of the second mesa structure 470.

As described above, it is not required for all mesa structures formed in an APD to have a stepped structure. The effects of the present invention can be obtained as long as the mesa structure having a light-receiving function has such a stepped structure as described above.

The present invention provides improvement in high-speed operation and reliability in an avalanche photodiode having a mesa structure. The example implementations of the present invention achieve the above-mentioned improvement by a mesa structure including a multiplication layer, a light absorption layer, and a contact layer, in which the multiplication layer is larger than the light absorption layer and the light absorption layer is larger than the contact layer in plan view. In other words, in a cross-sectional view of the mesa structure, the mesa structure has a three-stage structure of a lower stage including the multiplication layer, a middle stage including the light absorption layer, and an upper stage including the contact layer. The side surfaces of the multiplication layer, the light absorption layer, and the contact layer are not flush with each other. An electric field control layer may be placed between the multiplication layer and the light absorption layer. The electric field control layer is formed of a material different from that of the light absorption layer. The electric field control layer is included in the lower stage or the middle stage of the mesa structure. The uppermost layer of the middle stage of the mesa structure may include an etching stop layer. The etching stop layer is formed of a material different from that of the lowermost layer of the upper stage. The light absorption layer may have a two-layer structure of an undoped absorption layer placed on the multiplication layer side and a low-concentration absorption layer placed on the contact layer side. In this case, the low-concentration absorption layer is depleted when a voltage is applied thereto. An electron transit layer and an electric field reduction layer may be included between the multiplication layer and a substrate. The electron transit layer and the electric field reduction layer are included in the lower stage of the mesa structure. The avalanche photodiode may be of a top-illuminated type or of a back-illuminated type. In a case of the back-illuminated type, a lens may be formed on a surface of the substrate opposite to a surface on which the mesa structure is formed. The avalanche photodiode supports light of from 1,250 nm to 1,600 nm. The mesa structure has a circular shape in plan view, and the diameter of the multiplication layer is 1 μm or more larger than the diameter of the light absorption layer in plan view. The diameter of the light absorption layer is 1 μm or more larger than the diameter of the p-type contact layer in plan view.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. An avalanche photodiode, comprising:
a substrate;
an n-type contact layer formed above the substrate;
a multiplication layer formed above the n-type contact layer;
a light absorption layer formed above the multiplication layer; and
a p-type contact layer formed above the light absorption layer,
wherein the multiplication layer, the light absorption layer, and the p-type contact layer form a mesa structure,
wherein the multiplication layer is larger than the light absorption layer in plan view, and
wherein the light absorption layer is larger than the p-type contact layer in plan view.

2. The avalanche photodiode according to claim 1,
wherein the light absorption layer includes a first light absorption layer placed on the multiplication layer side and a second light absorption layer placed on the p-type contact layer side,
wherein the first light absorption layer comprises an undoped layer, and
wherein the second light absorption layer comprises a low-concentration p-type layer.

3. The avalanche photodiode according to claim 2, wherein the second light absorption layer is depleted when a voltage is applied thereto.

4. The avalanche photodiode according to claim 1, further comprising an electric field control layer between the multiplication layer and the light absorption layer.

5. The avalanche photodiode according to claim 4, wherein the electric field control layer is the same in size as the multiplication layer in plan view.

6. The avalanche photodiode according to claim 5, wherein the electric field control layer is formed of a material different from a material of the light absorption layer.

7. The avalanche photodiode according to claim 1, further comprising an etching stop layer between the light absorption layer and the p-type contact layer.

8. The avalanche photodiode according to claim 7, wherein the etching stop layer is the same in size as the light absorption layer in plan view.

9. The avalanche photodiode according to claim 8, wherein the etching stop layer is formed of a material different from a material of the p-type contact layer.

10. The avalanche photodiode according to claim 1, further comprising, between the multiplication layer and the substrate, an electron transit layer placed on the substrate side and an electric field reduction layer placed on the multiplication layer side.

11. The avalanche photodiode according to claim 1, further comprising:
a p-side electrode that is in contact with the p-type contact layer; and
an n-side electrode that is in contact with the n-type contact layer.

12. The avalanche photodiode according to claim 11,
wherein the mesa structure comprises a first mesa structure having an uppermost surface on which the p-side electrode is placed, and
wherein the avalanche photodiode further comprises a second mesa structure including the same semiconductor multilayer as a semiconductor multilayer of the first mesa structure and having an uppermost surface on which a part of the n-side electrode is placed.

13. The avalanche photodiode according to claim 12, wherein the second mesa structure has a stepless side surface in cross-sectional view.

14. The avalanche photodiode according to claim 1, wherein the avalanche photodiode is of a top-illuminated type in which light enters from the p-type contact layer side.

15. The avalanche photodiode according to claim 1, wherein the avalanche photodiode is of a back-illuminated type in which light enters from the substrate side.

16. The avalanche photodiode according to claim 15, wherein the substrate has a lens formed on a surface of the substrate on a side from which the light enters.

17. The avalanche photodiode according to claim 1,
wherein the mesa structure has a circular shape in plan view,
wherein a diameter of the multiplication layer is 1 μm or more larger than a diameter of the light absorption layer in plan view, and
wherein the diameter of the light absorption layer is 1 μm or more larger than a diameter of the p-type contact layer in plan view.

18. The avalanche photodiode according to claim 4, wherein spread of an electric field applied to the mesa structure reaches a side surface of the light absorption layer before reaching an interface between the light absorption layer and the electric field control layer.
